(19) United States
(12) Patent Application Publication
(10) Pub. No.: US 2026/0068232 A1
(43) Pub. Date: Mar. 5, 2026

(54) THIN FILM TRANSISTOR, METHOD FOR MANUFACTURING THE SAME AND DISPLAY APPARATUS COMPRISING THE SAME

(71) Applicant: LG Display Co., Ltd., Seoul (KR)

(72) Inventors: HyunCheol CHO, Paju-si (KR); ChanYong JEONG, Paju-si (KR); Minho LEE, Paju-si (KR); DaeHwan KIM, Paju-si (KR)

(73) Assignee: LG Display Co., Ltd., Seoul (KR)

(21) Appl. No.: 19/280,012

(22) Filed: Jul. 24, 2025

(30) Foreign Application Priority Data
Aug. 28, 2024 (KR) 10-2024-0115768

(51) Int. Cl. H10D 30/67; H10D 86/40

(52) U.S. Cl. CPC H10D 30/6757; H10D 30/6755; H10D 86/423

(57) ABSTRACT

One embodiment of the present disclosure provides a thin film transistor including a seed layer having an inclined surface, an active layer contacting the seed layer and including a channel part, and a gate electrode overlapping at least a portion of the active layer. The channel part has a crystalline structure. The channel part is disposed on the inclined surface and contacts the inclined surface. At least a portion of the gate electrode is disposed to face the inclined surface with the active layer interposed therebetween. In addition, another embodiment of the present disclosure provides a manufacturing method of the thin film transistor and a display apparatus including the thin film transistor.

### CROSS-REFERENCE TO RELATED APPLICATION

This application claims the benefit of priority of the Republic of Korea Patent Application No. 10-2024-0115768 filed on Aug. 28, 2024, which is hereby incorporated by reference in its entirety.

### BACKGROUND

### Technical Field

The present disclosure relates to a thin film transistor having a seed layer, a method for manufacturing the thin film transistor, and a display apparatus including the thin film transistor.

### Description of the Related Art

The transistors are widely used as switching devices or driving devices in the field of electronic devices. In particular, thin film transistors are widely used as switching devices in display apparatuses such as liquid crystal display apparatuses or organic light emitting devices because they may be manufactured on glass or plastic substrates.

Thin film transistors may be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Since amorphous silicon may be deposited in a short period of time to form an active layer, amorphous silicon thin film transistors (a-Si TFT) have the advantages of a short manufacturing process time and low production costs. On the other hand, amorphous silicon thin film transistors have the disadvantages of limited use in active matrix organic light emitting diode (AMOLED) because of low mobility, poor current driving capability, and changes in threshold voltage.

Polycrystalline silicon thin film transistors (poly-Si TFT) are made by crystallizing amorphous silicon after amorphous silicon has been deposited. Polycrystalline silicon thin film transistors have the advantages of high electron mobility, excellent stability, thinness, high resolution, and high power efficiency. Examples of such polycrystalline silicon thin film transistors include low temperature poly-silicon (LTPS) thin film transistors, or polysilicon thin film transistors. Since the manufacturing process of polycrystalline silicon thin film transistors requires a process in which amorphous silicon is crystallized, the number of processes increases, which increases the manufacturing cost, and crystallization must be performed at a high process temperature.

### BRIEF SUMMARY

Oxide semiconductor thin film transistors that have high mobility and a large resistance variation depending on the oxygen content have the advantage of being able to easily obtain desired property. In addition, since the oxide constituting the active layer may be formed at a relatively low temperature during the manufacturing process of oxide semiconductor thin film transistors, the manufacturing cost is low. Since oxide semiconductors are transparent due to the nature of oxides, they are also advantageous in implementing transparent displays.

However, the performance of oxide semiconductor thin film transistors may be degraded and the turn-on voltage may become unstable due to hydrogen. In particular, when the oxide semiconductor thin film transistor is used in an environment containing a large amount of hydrogen or at a high temperature, the performance deterioration or performance instability due to hydrogen may become severe. Therefore, in order to prevent deterioration of the oxide semiconductor thin film transistor and improve stability, it is necessary to protect the oxide semiconductor thin film transistor from hydrogen.

In addition, electronic products have become more highly integrated recently. In addition, the demand for high-resolution display apparatuses is increasing. For high integration and high resolution, the size and area of thin film transistors need to be reduced. Therefore, it is required to manufacture thin film transistors in a narrow area.

The disclosed thin film transistor structure features a vertical configuration that employs a seed layer with an inclined surface to enable selective crystallization of the active layer. This results in a crystalline channel region while maintaining amorphous regions at the source and drain contacts. The structure supports high carrier mobility and enhanced resistance to hydrogen degradation, making it suitable for applications requiring high resolution and component density. The seed layer, formed from oxide semiconductor materials with low carrier concentration, facilitates controlled crystallization during thermal treatment at temperatures between 300 and 500 degrees Celsius. The active layer may include specific dopants to manage crystallization behavior and improve electrical conductivity.

The design also includes configurations where the seed layer has a concave geometry, allowing the channel length to be extended without increasing the surface area. This approach improves space utilization and supports integration into compact electronic devices. The described thin film transistors are compatible with display panels, including those using organic light emitting diodes, and can be implemented in gate driver circuits on the panel substrate. These features contribute to improved reliability, electrical stability, and manufacturing efficiency.

For example, one embodiment of the present disclosure provides a thin film transistor including a seed layer having an inclined surface, and a gate electrode disposed to face the inclined surface of the seed layer. One embodiment of the present disclosure provides a thin film transistor having a vertical structure including a channel part disposed on the inclined surface of the seed layer.

One embodiment of the present disclosure is to provide a thin film transistor having a vertical structure capable of securing a channel length even within a limited area.

One embodiment of the present disclosure is to provide a thin film transistor having a narrow area.

One embodiment of the present disclosure is to provide a thin film transistor having a crystallized channel part and excellent resistance to hydrogen.

Another embodiment of the present disclosure provides a manufacturing method of a thin film transistor having a vertical structure by using an oxide semiconductor material having conductor property and a seed layer.

Another embodiment of the present disclosure is to provide a display apparatus having excellent reliability, including a thin film transistor as described above.

One embodiment of the present disclosure for achieving the above described technical subject provides a thin film transistor including a seed layer having an inclined surface, an active layer contacting the seed layer and including a channel part, and a gate electrode overlapping at least a portion of the active layer, wherein the channel part has a crystalline structure, wherein the channel part is disposed on the inclined surface and contacts the inclined surface, and wherein at least a portion of the gate electrode is disposed to face the inclined surface with the active layer interposed therebetween.

The active layer may further include a first connection part connected to one side of the channel part and a second connection part connected to the other side of the channel part, and the first connection part and the second connection part may each have an amorphous structure.

The first connection part and the second connection part do not contact the seed layer.

In a plan view, in a portion where the gate electrode is disposed, a width of the seed layer is greater than a width of the active layer. Here, the width of the seed layer and the width of the active layer are measured in a direction perpendicular to a line connecting the first connection part and the second connection part.

The above seed layer may have an amorphous structure.

The seed layer is an amorphous layer in which a ratio of a sum of areas of the crystals having a grain size of 1 nm or more is 10% or less to an entire cross-sectional area in a cross-section of the seed layer.

The seed layer may have a lower carrier concentration than the channel part.

The seed layer may have a carrier concentration of 1.0×10¹⁶ ea/cm³ or less.

The seed layer may include at least one oxide semiconductor material of an IZO (InZnO) based oxide semiconductor material, an IGZO (InGaZnO) based oxide semiconductor material, an IGZTO (InGaZnSnO) based oxide semiconductor material, a GZTO (GaZnSnO) based oxide semiconductor material, a GZO (GaZnO) based oxide semiconductor material, and a GO (GaO) based oxide semiconductor material.

The active layer may include at least one of an IGZO (InGaZnO) based, IGO (InGaO) based, IGZTO (InGaZnSnO) based, GZTO (GaZnSnO) based, GZO (GaZnO) based, GO (GaO) based, TO (SnO) based, ITO (InSnO) based, ITZO (InSnZnO) based, IZO (InZnO) based, ZO (ZnO) based, InO (InO) based, and FIZO (FeInZnO) based oxide semiconductor material.

The active layer may further include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), and zirconium (Zr).

The seed layer and the active layer may include at least one common metal element.

In a cross-section the channel part, a ratio of sum of areas of crystals having a grain size of 1 nm or more is 50% or more to an entire cross-sectional area.

The channel part may include at least one of ta (400) crystal plane, a (222) crystal plane, a (220) crystal plane, a (311) crystal plane, and a (001) crystal plane.

The thin film transistor further includes a source electrode and a drain electrode spaced apart from each other, wherein the source electrode may contact the seed layer and the first connection part, and wherein the drain electrode may contact the seed layer and the second connection part.

The seed layer may have a concave part, wherein the concave part may be defined by the inclined surface and the bottom surface, and wherein the active layer may be disposed on the inclined surface and the bottom surface of the concave part.

The bottom surface may be a part of the seed layer, and the channel part may be extended form on the inclined surface to on the bottom surface.

The thin film transistor may further include a metal layer disposed on the bottom surface of the concave part, and wherein the active layer may further include a third connection part contacting the metal layer.

The third connection part may have an amorphous structure.

Another embodiment of the present disclosure provides a display apparatus including the thin film transistor described above.

Another embodiment of the present disclosure provides a manufacturing method of a thin film transistor comprising forming a seed material layer on a substrate, forming a seed layer having an inclined surface by patterning the seed material layer, forming an active layer contacting the inclined surface of the seed layer, heat treating the active layer to crystallize a portion of the active layer contacting the inclined surface, and forming a gate electrode on the active layer, wherein at least a portion of the gate electrode may be disposed to face the inclined surface with the active layer interposed therebetween

Before the heat treating, the active layer may have an amorphous structure.

A temperature of the heat treating may be in the range of 300 to 500° C.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor according to another embodiment of the present disclosure.

FIG. 5 is a cross-sectional view taken along line III-III′ of FIG. 4.

FIG. 6 is a plan view of a thin film transistor according to another embodiment of the present disclosure.

FIG. 7 is a cross-sectional view taken along line IV-IV′ of FIG. 6.

FIG. 8 is a plan view of a thin film transistor according to another embodiment of the present disclosure.

FIG. 9 is a cross-sectional view taken along line V-V′ of FIG. 8.

FIGS. 10A to 10I are cross-sectional views illustrating a manufacturing method of a thin film transistor according to one embodiment of the present disclosure.

FIG. 11 is a schematic diagram of a display apparatus according to another embodiment of the present disclosure.

FIG. 12 is a circuit diagram for one pixel of FIG. 11.

FIG. 13 is a plan view of the pixels of FIG. 12.

FIG. 14 is a cross-sectional view taken along line IX-IX′ of FIG. 13.

### DETAILED DESCRIPTION

The advantages and features of the present disclosure, and the method for achieving them, will become clear with reference to the embodiments described in detail below together with the accompanying drawings. However, the present disclosure is not limited to the embodiments disclosed below, and may be implemented in various other forms. These embodiments are provided to ensure that the disclosure of the present disclosure is complete, and to enable those skilled in the art to easily understand the disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same components may be referred to by the same reference numerals throughout the specification. In addition, in explaining the present disclosure, if it is determined that a detailed description of a related known technology may unnecessarily obscure the gist of the present disclosure, the detailed description is omitted.

In this specification, when the words “includes,” “has,” and “consists of,” are used, other parts may be added unless the expression “only” is used. When a component is expressed in the singular, the plural is included unless otherwise explicitly stated.

When interpreting a component, it is interpreted as including the error range even though there is no separate explicit description.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When describing a positional relationship, for example, when the positional relationship between two parts is described as ‘on’, ‘above’, ‘below’, ‘next to’, or the like, one or more other parts may be located between the two parts, unless the expression ‘right’ or ‘directly’ is used.

The spatially relative terms “below,” “beneath,” “lower,” “above,” “upper,” and the like may be used to easily describe the relationship of one element or component to another element or component, as illustrated in the drawings. The spatially relative terms should be understood to include different orientations of the elements during use or operation in addition to the orientations depicted in the drawings. For example, if an element illustrated in the drawings is flipped over, an element described as “below” or “beneath” another element may end up being placed “above” the other element. Thus, the exemplary term “below” can include both the above and below directions. Likewise, the exemplary term “above” or “above” can include both the above and below directions.

When describing a temporal relationship, for example, when describing a temporal relationship such as ‘after’, ‘following’, ‘next to’, or ‘before’, it can also include cases where there is no continuity, as long as the expression ‘right away’ or ‘directly’ is not used.

Although the terms first, second, or the like. are used to describe various components, these components are not limited by these terms. These terms are only used to distinguish one component from another. Accordingly, a first component referred to below may also be a second component within the technical concept of the present disclosure.

At least one term should be understood to include all combinations that may be presented from one or more of the associated items. For example, the meaning of “at least one of the first, second, and third items” can mean not only each of the first, second, or third items, but also all combinations of items that may be presented from two or more of the first, second, and third items.

The individual features of the various embodiments of the present disclosure may be partially or wholly combined or combined with each other, and may be technically linked and driven in various ways, and each embodiment may be implemented independently of each other or may be implemented together in a related relationship.

Hereinafter, a thin film transistor and a display apparatus including the same according to an embodiment of the present disclosure will be described in detail with reference to the attached drawings. When adding reference symbols to components in each drawing, the same components may have the same symbols as much as possible even though they are shown in different drawings.

In embodiments of the present disclosure, the source electrode and the drain electrode are distinct, but the source electrode and the drain electrode may be interchanged. For example, the source electrode according to one embodiment may become the drain electrode in another embodiment, and the drain electrode according to one embodiment may become the source electrode in another embodiment.

In the embodiments of the present disclosure, for the convenience of explanation, the source region and the source electrode are distinguished, and the drain region and the drain electrode are distinguished, but the embodiments of the present disclosure are not limited thereto. The source region may be the source electrode, and the drain region may be the drain electrode. In addition, the source region may be the drain electrode, and the drain region may be the source electrode.

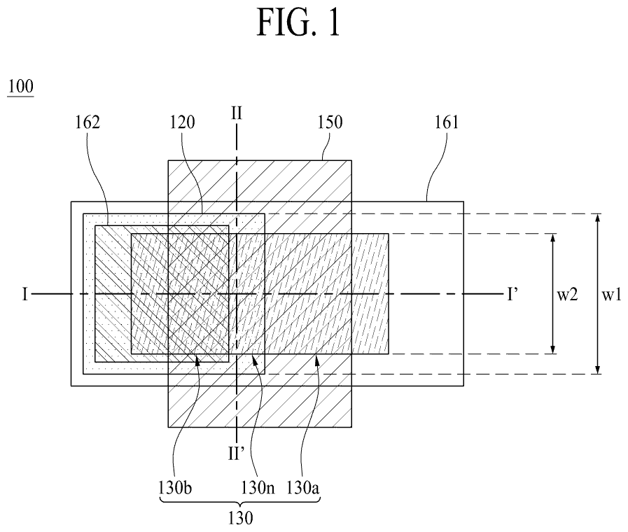

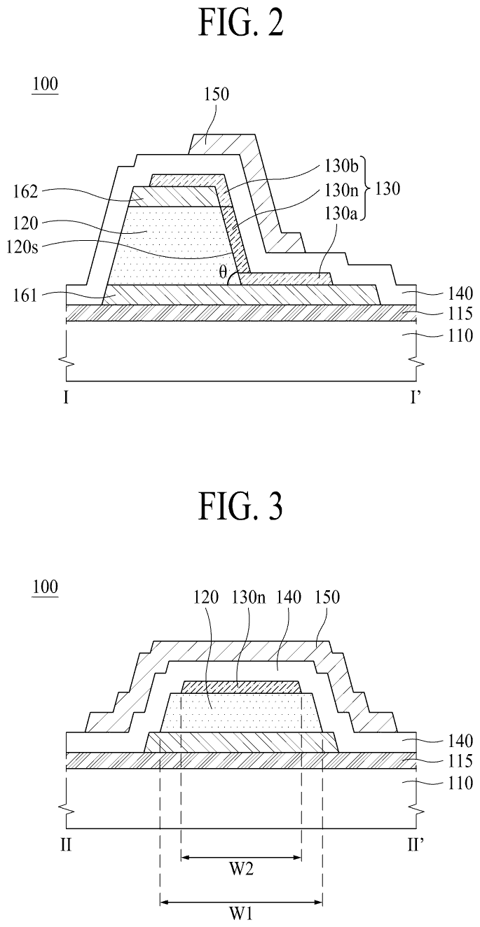

FIG. 1 is a plan view of a thin film transistor 100 according to one embodiment of the present disclosure, FIG. 2 is a cross-sectional view taken along line I-I′ of FIG. 1, and FIG. 3 is a cross-sectional view taken along line II-II′ of FIG. 1.

The thin film transistor 100 according to one embodiment of the present disclosure includes a seed layer 120 having an inclined surface 120s, an active layer 130 contacting the seed layer 120, and a gate electrode 150 at least partially overlapping the active layer 130. The active layer 130 includes a channel part 130n. The channel part 130n has a crystalline structure.

The channel part 130n is disposed on the inclined surface 120s of the seed layer 120 and contacts the inclined surface 120s. At least a portion of the gate electrode 150 is arranged facing the inclined surface 120s of the seed layer 120 with the active layer 130 interposed therebetween.

Referring to FIGS. 2 and 3, a thin film transistor 100 may be disposed on a substrate 110. Anything that supports the thin film transistor 100 may be referred to as a substrate 110 without limitation.

The Glass or plastic may be used as the substrate 110. A transparent plastic having flexible property may be used as the substrate 110. Among the plastics, for example, when polyimide is used as the substrate 110, considering that a high-temperature deposition process is performed on the substrate 110, a heat-resistant polyimide that can withstand high temperatures may be used.

A buffer layer 115 may be disposed on the substrate 110. The buffer layer 115 may be made of an insulating material. For example, the buffer layer 115 may include at least one of an insulating material such as silicon oxide, silicon nitride, and a metal oxide. The buffer layer 115 may have a single-film structure or a multi-film structure. The buffer layer 115 may protect the active layer 130 by blocking air and moisture. The surface of the upper portion of the substrate 110 may be made uniform by the buffer layer 115.

The buffer layer 115 may be omitted.

A source electrode 161 may be disposed on the buffer layer 115. The source electrode 161 may also be placed directly on the substrate 110. However, one embodiment of the present disclosure is not limited thereto, and the source electrode 161 may also be disposed on the seed layer 120.

The seed layer 120 may be disposed on the source electrode 161. However, one embodiment of the present disclosure is not limited thereto, and the seed layer 120 may be placed directly on the substrate 110. The seed layer 120 may also be disposed on the buffer layer 115.

The seed layer 120 selectively crystallizes a portion of the active layer 130 that comes into contact with the seed layer 120. The seed layer 120 acts as a seed for crystal growth. A selected portion of the active layer 130 may be crystallized by the seed layer 120. As a result, a portion of the active layer 130 may have crystallinity.

According to one embodiment of the present disclosure, the seed layer 120 may include an oxide semiconductor material.

For example, the seed layer 120 may include at least one of an IZO (InZnO) based oxide semiconductor material, an IGZO (InGaZnO) based oxide semiconductor material, an IGZTO (InGaZnSnO) based oxide semiconductor material, a GZTO (GaZnSnO) based oxide semiconductor material, a GZO (GaZnO) based oxide semiconductor material, and a GO (GaO) based oxide semiconductor material.

According to one embodiment of the present disclosure, the seed layer 120 may have a basic composition made of an oxide semiconductor material, but includes a large amount of oxygen. As a result, the seed layer 120 may have the characteristic of an insulating layer in terms of electrical property. The seed layer 120 only selectively crystallizes the active layer 130, and does not affect the electrical characteristic of the active layer 130.

In detail, the seed layer 120 may be formed by an oxide semiconductor material having a low carrier concentration and a high oxygen concentration. The seed layer 120 according to one embodiment of the present disclosure may have a high resistivity. The seed layer 120 having a high resistivity has electrical characteristic similar to an insulator and does not participate in the carrier movement of the active layer 130. According to one embodiment of the present disclosure, the seed layer 120 may have a lower carrier concentration than the channel part 130n of the active layer 130.

According to one embodiment of the present disclosure, the seed layer 120 may have a carrier concentration of 1.0×10¹⁶ ea/cm³ or less. When the carrier concentration of the seed layer 120 is 1.0×10¹⁶ ea/cm³ or less, the seed layer 120 may have electrical characteristic close to an insulating layer.

According to one embodiment of the present disclosure, the seed layer 120 may have a low carrier concentration of 1.0×10¹⁶ ea/cm³ or less and thus has insulating property. Accordingly, the seed layer 120 may not affect the on-current characteristic of the thin film transistor 100.

The seed layer 120 may have an amorphous structure. According to one embodiment of the present disclosure, the seed layer 120 may be an amorphous layer.

According to one embodiment of the present disclosure, when a ratio of a sum of areas of crystals having a grain size of 1 nm or more is 10% or less to an entire cross-sectional area based on a cross-section of a layer, the layer is called an amorphous layer. In detail, based on a transmission electron microscope (TEM) image of a cross-section of a layer to be measured, when the ratio of a sum of areas of crystals having a grain size of 1 nm or more is 10% or less to an entire area of the cross-sectional area, the layer is called an amorphous layer.

According to one embodiment of the present disclosure, the seed layer 120 may be an amorphous layer in which the proportion of a sum of areas of crystals having a grain size of 1 nm or more is 10% or less to an entire cross-sectional area based on a cross-section.

On the other hand, if a ratio of a sum of areas of crystals having a grain size of 1 nm or more is 50% or more to an entire cross-sectional area based on a cross-section of a layer, the layer is called a crystalline layer. In detail, based on a transmission electron microscope (TEM) image of a cross-section of a layer to be measured, if the ratio of a sum of areas of crystals having a grain size of 1 nm or more is 50% or more to an entire cross-sectional area, the layer is called a crystalline layer.

Referring to FIG. 2, the seed layer 120 may have an inclined surface 120s. After a seed material layer may be formed by a material for forming the seed layer 120, the seed material layer may be patterned so that a seed layer 120 having an inclined surface 120s may be formed.

The inclined surface 120s of the seed layer 120 may have a predetermined inclination angle θ based on the upper surface of the substrate 110. According to one embodiment of the present disclosure, the angle between the upper surface of the substrate 110 and the inclined surface 120s of the seed layer 120 is referred to as the inclination angle θ. When the upper surface of the source electrode 161 and the upper surface of the substrate 110 are parallel to each other, as illustrated in FIG. 2, the angle between the upper surface of the source electrode 161 and the inclined surface 120s of the seed layer 120 may be referred to as the inclination angle θ.

The drain electrode 162 may be disposed on the seed layer 120. In one embodiment of the present disclosure, the source electrode 161 and the drain electrode 162 are distinguished only for convenience of explanation, and the source electrode 161 and the drain electrode 162 are not limited to FIG. 2. In FIG. 2, the positions of the source electrode 161 and the drain electrode 162 may be exchanged.

The source electrode 161 and the drain electrode 162 may each include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 may each be formed of a single layer made of a metal or an alloy of metals, or may be formed of a multilayer of two or more layers.

According to one embodiment of the present disclosure, an active layer 130 may be disposed on a seed layer 120. At least a portion of the active layer 130 may contact the seed layer 120.

Referring to FIG. 2 and FIG. 3, an active layer 130 may be disposed on the source electrode 161, the drain electrode 162, and the seed layer 120. The active layer 130 is disposed on the inclined surface 120s of the seed layer 120. At least a portion of the active layer 130 may contact the inclined surface 120s of the seed layer 120.

According to one embodiment of the present disclosure, the active layer 130 includes a channel part 130n. In addition, the active layer 130 includes a first connection part 130a connected to one side of the channel part 130n and a second connection part 130b connected to the other side of the channel part 130n.

According to one embodiment of the present disclosure, the channel part 130n may have a crystalline structure. The first connection part 130a and the second connection part 130b each may have an amorphous structure.

According to one embodiment of the present disclosure, the active layer 130 may be formed of a semiconductor material. The active layer 130 may include an oxide semiconductor material. The active layer 130 may include, for example, an oxide semiconductor layer.

In FIGS. 1 to 3, a thin film transistor 100 in which the active layer 130 is an oxide semiconductor layer is illustrated as an example.

According to one embodiment of the present disclosure, the active layer 130 may be formed by an oxide semiconductor material having a high mobility similar to that of a conductor. For example, the active layer 130 may be formed by an amorphous oxide semiconductor material having a carrier concentration of 1.0×10¹⁹ ea/cm³ or more. On the other hand, the seed layer 120 may be formed by an amorphous oxide semiconductor material having a lower carrier concentration than that of the active layer 130.

The active layer 130 may include, for example, at least one of an IGZO (InGaZnO) based oxide semiconductor material, an IGO (InGaO) based oxide semiconductor material, an IGZTO (InGaZnSnO) based oxide semiconductor material, a GZTO (GaZnSnO) based oxide semiconductor material, a GZO (GaZnO) based oxide semiconductor material, a GO (GaO) based oxide semiconductor material, a TO (SnO) based oxide semiconductor material, an ITO (InSnO) based oxide semiconductor material, an ITZO (InSnZnO) based oxide semiconductor material, an IZO (InZnO) based oxide semiconductor material, a ZO (ZnO) based oxide semiconductor material, an InO (InO) based oxide semiconductor material, and a FIZO (FeInZnO) based oxide semiconductor material. However, one embodiment of the present disclosure is not limited thereto, and other known oxide semiconductor materials having high mobility may be applied to the active layer 130 according to one embodiment of the present disclosure.

According to one embodiment of the present disclosure, an indium based oxide semiconductor material having an indium (In) content of 50 atom % (at %) or more based on the number of atoms among all metal elements may be used as an oxide semiconductor material for forming an active layer 130. The active layer 130 may include, for example, at least one of an IZO (InZnO) based oxide semiconductor material, an IGO (InGaO) based oxide semiconductor material, an IGZO (InGaZnO) based oxide semiconductor material, an ITO (InSnO) based oxide semiconductor material, and an IGZTO (InGaZnSnO) based oxide semiconductor material having an indium (In) content of 50 atom % (at %) or more based on the number of atoms among all metal elements.

In detail, the active layer 130 may include an IZO based oxide semiconductor material having an indium (In) content of 50 at % or more relative to the total content of indium (In) and zinc (Zn), an IGO based oxide semiconductor material having an indium (In) content of 70 at % or more relative to the total content of indium (In) and gallium (Ga), an IGZO based oxide semiconductor material having an indium (In) content of 50 at % or more relative to the total content of indium (In), gallium (Ga), and zinc (Zn), an ITO based oxide semiconductor material having an indium (In) content of 80 at % or more relative to the total content of indium (In) and tin (Sn), and an IGZTO based oxide semiconductor material having a mixed content of indium (In) and tin (Sn) of 50 at % or more relative to the total content of indium (In), gallium (Ga), zinc (Zn), and tin (Sn).

According to one embodiment of the present disclosure, the active layer 130 may have a low oxygen concentration. When the active layer 130 includes a high concentration of indium (In) and a low concentration of oxygen, the active layer 130 may have high mobility characteristic and excellent electrical conductivity.

According to one embodiment of the present disclosure, the active layer 130 may include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), and zirconium (Zr). The above elements may be dispersed in the oxide semiconductor material.

According to one embodiment of the present disclosure, beryllium (Be), boron (B), carbon (C), aluminum (Al), silicon (Si), iron (Fe), calcium (Ca), tin (Sn), titanium (Ti), tantalum (Ta), vanadium (V), yttrium (Y), and zirconium (Zr) may be referred to as crystallization controlling elements.

The crystallization control element is an element that has a strong bonding force with oxygen and can delay the crystallization speed of the active layer 130. The active layer 130 may be formed by deposition and patterning, and the crystallization control element prevents crystallization of the active layer 130 during the deposition process, thereby preventing the patterning property of the active layer 130 from deteriorating.

On the other hand, crystallization control does not completely prevent crystallization of the active layer 130. As a result, if heat treatment is performed while the active layer 130 may contact the seed layer 120, a portion of the active layer 130 contacting the seed layer 120 may be crystallized.

According to one embodiment of the present disclosure, the crystallization control element may have a content of 0.1 to 6 atomic % (at %) with respect to the total atoms of the active layer 130 excluding oxygen. When the content of the crystallization control element is less than 0.1 atomic % (at %) with respect to the total atoms of the active layer 130 excluding oxygen, the crystallization prevention effect may not be sufficiently exerted during the deposition process. As a result, difficulties may occur during the patterning process after deposition of the oxide semiconductor material for forming the active layer 130.

On the other hand, if the content of the crystallization control element exceeds 6 atom % at % with respect to the total atoms of the active layer 130 excluding oxygen, a selected portion of the active layer 130 may not be crystallized or the crystallization rate may be reduced due to the excessive amount of the crystallization control element.

According to one embodiment of the present disclosure, the active layer 130 and the seed layer 120 may include at least one common metal element. When the active layer 130 and the seed layer 120 include the same element, the bonding strength between the active layer 130 and the seed layer 120 may be improved.

According to one embodiment of the present disclosure, after an active layer 130 may be formed by an amorphous oxide semiconductor material, a region of the active layer 130 that contacts the seed layer 120 is crystallized, thereby forming a channel part 130n.

According to one embodiment of the present disclosure, the change of a portion having an amorphous structure into a crystalline structure is called “crystallization.” In addition, the crystallization of only a specific portion of the active layer 130 is called “selective crystallization.”

According to one embodiment of the present disclosure, the channel part 130n may be a portion of the active layer 130 that is crystallized by the seed layer 120. Alternatively, the channel part 130n may be a portion that is selectively crystallized by the seed layer 120.

For example, selective crystallization of the active layer 130 may occur when oxygen contained in the seed layer 120 diffuses to the active layer 130 in contact with the seed layer 120. The seed layer 120 acts as a seed for crystallization. Using the seed layer 120 as a seed, crystallization may proceed from a portion of the active layer 130 that contacts the seed layer 120.

In the process of crystallizing the active layer 130 contacting the seed layer 120 and forming the channel part 130n, movement of oxygen O may occur. Oxygen O may move from the seed layer 120 to the channel part 130n. As a result, the channel part 130n may have a higher oxygen concentration than the first connection part 130a and the second connection part 130b. However, the oxygen concentration of the channel part 130n does not become higher than the oxygen concentration of the seed layer 120.

According to one embodiment of the present disclosure, the channel part 130n may have a lower oxygen concentration than the seed layer 120. The oxygen concentration may be expressed in atomic percent at %.

According to one embodiment of the present disclosure, in a cross-section of the channel part 130n, a ratio of a sum of areas of crystals having a crystal grain size of 1 nm or more may be 50% or more to an entire area of the cross-section. In detail, based on a transmission electron microscope (TEM) image of a cross-section of the channel part 130n, a ratio of a sum of areas of crystals having a grain size of 1 nm or more may be 50% or more to an entire area of the cross-section.

According to one embodiment of the present disclosure, the channel part 130n may include at least one crystal structure among, for example, a cubic crystal structure, a bixbyite crystal structure, a Cubic Bixbyite crystal structure, a spinel crystal structure, a hexagonal crystal structure, and a wurtzite crystal structure.

According to one embodiment of the present disclosure, the channel part 130n may have a crystal plane. The channel part 130n may include, for example, at least one of a (400) crystal plane, a (222) crystal plane, a (220) crystal plane, a (311) crystal plane, and a (001) crystal plane. The nodal plane may be identified or measured from X-ray diffraction analysis (XRD) of the channel part 130n of the active layer 130.

The channel part 130n having a crystalline structure may have excellent physical and chemical stability. As a result, damage to the channel part 130n or deformation of the physical property of the channel part 130n during the manufacturing process and use process of the thin film transistor 100 may be suppressed or prevented. In addition, since the channel part 130n has a crystalline structure, it may have excellent resistance to hydrogen. As a result, the channel part 130n may have excellent stability. According to one embodiment of the present disclosure, since the channel part 130n has excellent stability, the thin film transistor 100 may have excellent operating stability.

According to one embodiment of the present disclosure, the first connection part 130a and the second connection part 130b are non-crystallized portions. The first connection part 130a and the second connection part 130b may have excellent electrical conductivity similar to that of metal.

The channel part 130n has a lower carrier concentration than the first connection part 130a and the second connection part 130b. In addition, the channel part 130n may have a lower mobility than the first connection part 130a and the second connection part 130b.

Referring to FIG. 2, the first connection part 130a and the second connection part 130b do not contact the seed layer 120. The portion of the active layer 130 that contacts the seed layer 120 and its surroundings may be crystallized to become a channel part 130n, and the portion that does not contact the seed layer 120 may become the first connection part 130a and the second connection part 130b. The amorphous portion of the active layer 130 may become the first connection part 130a and the second connection part 130b.

The first connection part 130a and the second connection part 130b, which are not crystallized and exist in an amorphous state, may have excellent electrical conductivity. According to one embodiment of the present disclosure, the first connection part 130a and the second connection part 130b may each have a carrier concentration of 1.0×10¹⁹ ea/cm³ or more. In detail, the first connection part 130a and the second connection part 130b may each have a carrier concentration of 1.0×10²¹ ea/cm³ or more.

In addition, the first connection part 130a and the second connection part 130b may each have a sheet resistance of 10³Ω/□ or less. In detail, the first connection part 130a and the second connection part 130b may each have a sheet resistance of 10²Ω/□ or less.

The first connection part 130a and the second connection part 130b having high carrier concentration and low surface resistance may have electrical characteristic similar to those of a conductor without going through a separate conductorization process.

According to one embodiment of the present disclosure, the first connection part 130a and the second connection part 130b may be formed without performing a conductorization process on the active layer 130. As a result, diffusion of a conductorized region into the channel part 130n during the conductorization process may be prevented. In one embodiment of the present disclosure, the conductorization process may be referred to as a process of providing conductivity or improving conductivity to a selected part of a semiconductor layer or a selected part of the active layer 300.

According to one embodiment of the present disclosure, the first connection part 130a may contact the source electrode 161. The source electrode 161 is electrically connected to the first connection part 130a of the active layer 130. The drain electrode 162 is spaced apart from the source electrode 161 and contacts the second connection part 130b. The drain electrode 162 is electrically connected to the second connection part 130b of the active layer 130.

According to one embodiment of the present disclosure, the first connection part 130a may be a source region, and the second connection part 130b may be a drain region. According to one embodiment of the present disclosure, the first connection part 130a may serve as a source electrode, and the second connection part 130b may serve as a drain electrode. The first connection part 130a and the second connection part 130b may be interchanged.

In addition, according to one embodiment of the present disclosure, the active layer 130 may have a multilayer structure. For example, the active layer 130 may include a first oxide semiconductor layer and a second oxide semiconductor layer disposed on the first oxide semiconductor layer. In addition, the active layer 130 may further include a third oxide semiconductor layer on the second oxide semiconductor layer.

As illustrated in FIG. 1 and FIG. 2, a thin film transistor according to one embodiment of the present disclosure may include a source electrode 161 and a drain electrode 162 that are spaced apart from each other. The source electrode 161 may contact the seed layer 120 and the first connection part 130a. The drain electrode 162 may contact the seed layer 120 and the second connection part 130b.

Referring to FIG. 2 and FIG. 3, a gate insulating layer 140 may be disposed on an active layer 130. The gate insulating layer 140 may include at least one of silicon oxide, silicon nitride, and metal oxide. The gate insulating layer 140 may have a single layer or a multilayer structure. The gate insulating layer 140 may protect the channel part 130n.

Referring to FIG. 2, the gate insulating layer 140 may be disposed on the channel part 130n disposed on the inclined surface 120s of the seed layer 120. The channel part 130n of the active layer 130 and the gate electrode 150 may be spaced apart from each other by the gate insulating layer 140.

Additionally, the gate insulating layer 140 may be formed over the entire upper portion of the substrate 110. For example, the gate insulating layer 140 may cover all of the channel part 130n, the first connection part 130a, and the second connection part 130b except for the contact region.

However, one embodiment of the present disclosure is not limited thereto, and the gate insulating layer 140 may be patterned. For example, the gate insulating layer 140 may be patterned into a shape corresponding to the gate electrode 150.

The gate electrode 150 may be disposed on the gate insulating layer 140.

The gate electrode 150 may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode 150 may also have a multilayer structure including at least two conductive layers having different physical property.

The gate electrode 150 may overlap with the channel part 130n of the active layer 130. In addition, the seed layer 120 may overlap with the gate electrode 150.

According to one embodiment of the present disclosure, the active layer 130 is disposed between the seed layer 120 and the gate electrode 150. In addition, the channel part 130n may be disposed between the seed layer 120 and the gate electrode 150.

The channel part 130n of the active layer 130 may have semiconductor characteristic and may have electrical conductivity when voltage is applied to the gate electrode 150. In order for the thin film transistor 100 to be driven, the channel part 130n must be disposed within an area to which an electric field generated by the gate electrode 150 is applied. According to one embodiment of the present disclosure, the channel part 130n, which is a crystallized portion of the active layer 130, may be disposed within an area defined by the gate electrode 150.

Referring to FIG. 1 and FIG. 3, in a region overlapping the gate electrode 150 in a planar manner, the width w1 of the seed layer 120 is larger than the width of the active layer w2. According to one embodiment of the present disclosure, the width is measured in a direction perpendicular to a line connecting the first connection part 130a and the second connection part 130b.

If a part of the active layer 130 does not overlap with the seed layer 120 in the width direction, an electric short may occur. In detail, a part of the active layer 130 that does not overlap with the seed layer 120 will not be crystallized and will have a high carrier concentration, low electrical resistance, and high electrical conductivity. Therefore, if a part of the active layer 130 that does not overlap with the seed layer 120 extends from the first connection part 130a to the second connection part 130b along the width direction w1, w2 direction to form a connection part, current will flow through the connection part regardless of the on-off of the thin film transistor 100. As a result, a short or leakage current may occur between the first connection part 130a and the second connection part 130b, and the thin film transistor 100 may not be able to perform a switching function.

To prevent such short or leakage current, according to one embodiment of the present disclosure, the width w1 of the seed layer 120 in the area overlapping the gate electrode 150 in a plane is designed to be larger than the width of the active layer w2.

In addition, the thin film transistor 100 according to one embodiment of the present disclosure may have a vertical structure including a channel part 130n disposed on an inclined surface 120s of a seed layer 120. According to one embodiment of the present disclosure, since the thin film transistor 100 may have a vertical structure, the length of the channel part 130n may be secured even in a narrow area. In addition, the area occupied by the thin film transistor 100 is small, and the thin film transistor 100 may be formed within a narrow area.

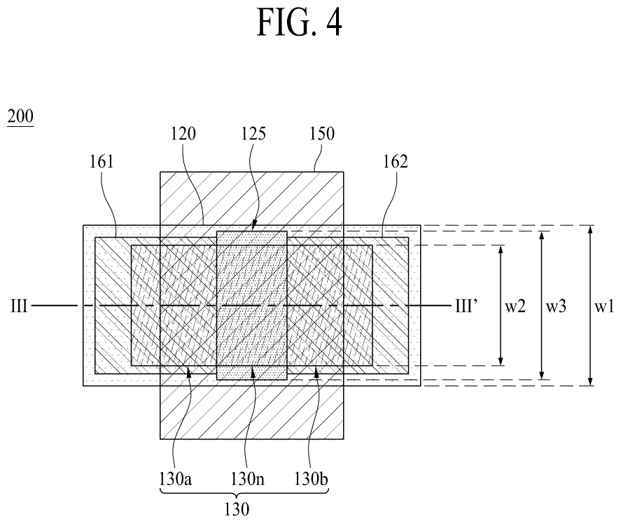

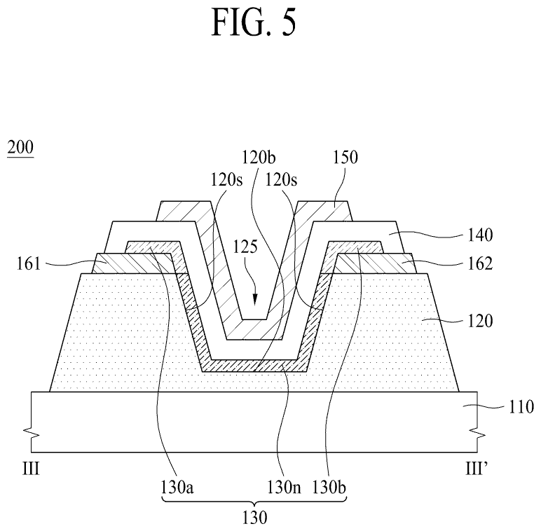

FIG. 4 is a plan view of a thin film transistor 200 according to another embodiment of the present disclosure, and FIG. 5 is a cross-sectional view taken along line III-III′ of FIG. 4.

Referring to FIG. 4 and FIG. 5, the seed layer 120 may have a concave part 125. The concave part 125 of the seed layer 120 may have an inclined surface 120s and a bottom surface 120b. The concave part 125 may be defined by the inclined surface 120s and the bottom surface 120b. According to another embodiment of the present disclosure, a space surrounded by the inclined surface 120s and the bottom surface 120b may be referred to as a concave part 125.

Referring to FIG. 5, the bottom surface 120b of the concave part 125 may be a part of the seed layer 120. In detail, according to another embodiment of the present disclosure, the bottom surface 120b of the concave part 125 may be a part of the surface of the seed layer 120. In addition, the inclined surface 120s of the concave part 125 may be also another part of the surface of the seed layer 120.

The active layer 130 may be disposed on the inclined surface 120s and the bottom surface 120b of the concave part 125. The active layer 130 may be disposed across the inclined surface 120s and the bottom surface 120b of the concave part 125.

The active layer 130 may contact the seed layer 120 on the inclined surface 120s of the concave part 125. In addition, the active layer 130 may contact the seed layer 120 on the bottom surface 120b of the concave part 125. A portion of the active layer 130 that contacts the inclined surface 120s and the bottom surface 120b of the concave part 125 may be crystallized to become a channel part 130n. According to another embodiment of the present disclosure, the channel part 130n may be extended from on the inclined surface 120s to on the bottom surface 120b. In detail, a portion of the channel part 130n on the inclined surface 120s and a portion of the channel part 130n on the bottom surface 120b may be connected each other.

The gate electrode 150 may overlap the active layer 130. The gate electrode 150 may be disposed facing the inclined surface 120s with the active layer 130 interposed therebetween. In addition, the gate electrode 150 may be disposed facing the bottom surface 120b with the active layer 130 interposed therebetween.

When the seed layer 120 may have a concave part 125, the channel part 130n may have a curved shape. Accordingly, the length of the channel part 130n may be increased. In detail, when the channel part 130n may have a curve formed along the longitudinal direction, compared to the case where the channel part 130n does not have a curve based on the same plane, the effect of the length of the channel part 130n being increased may occur. Here, the longitudinal direction is the direction connecting the first connection part 130a and the second connection part 130b.

A thin film transistor 200 according to another embodiment of the present disclosure includes a source electrode 161 and a drain electrode 162. The source electrode 161 and the drain electrode 162 are spaced apart from each other and each contacts the active layer 130. The source electrode 161 and the drain electrode 162 may be disposed on a seed layer 120.

Referring to FIG. 5, the source electrode 161 and the drain electrode 162 are disposed on the upper surface of the seed layer 120, and the active layer 130 may be disposed on the upper surface of the source electrode 161 and the upper surface of the drain electrode 162. The portion of the active layer 130 disposed on the source electrode 161 and the portion disposed on the drain electrode 162 may not be crystallized and may have excellent electrical conductivity. The portion of the active layer 130 disposed on the source electrode 161 may become a first connection part 130a, and the portion of the active layer 130 disposed on the drain electrode 162 may become a second connection part 130b.

The concave part 125 of the seed layer 120 may have a predetermined width w3. The width w3 of the concave part 125 may be greater than the width w2 of the active layer w3>w2. When the width w3 of the concave part 125 is greater than the width w2 of the active layer, the channel part 130n may have a curve over the entire width direction. As a result, the effect of the length of the channel part 130n becoming longer may occur over the entire width direction of the channel part 130n.

The width w3 of the concave part 125 may be smaller than the width w1 of the seed layer 120, w3<w1, or the width w3 of the concave part 125 may be equal to the width w1 of the seed layer 120, w3=w1. In addition, the width w3 of the concave part 125 may be smaller than the width w2 of the active layer, w3<w2.

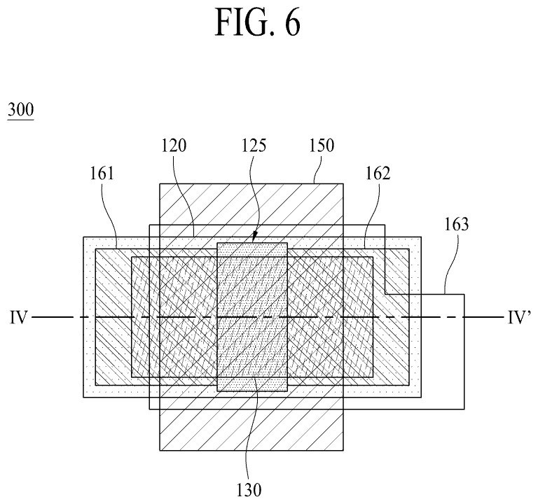

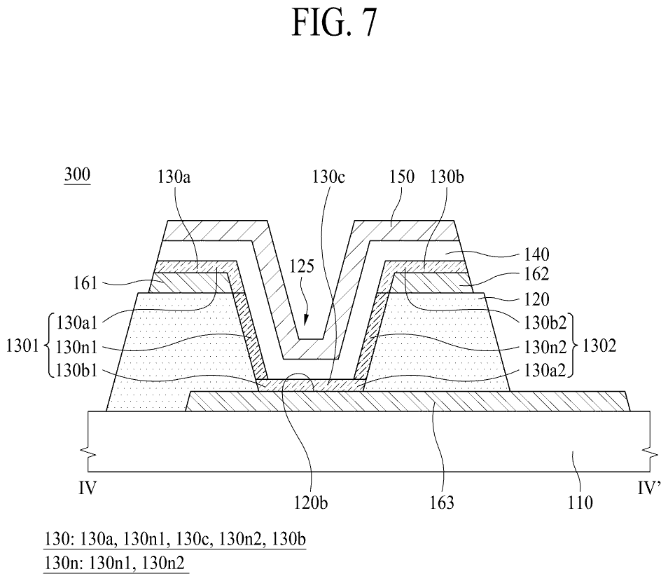

FIG. 6 is a plan view of a thin film transistor 300 according to another embodiment of the present disclosure, and FIG. 7 is a cross-sectional view taken along line IV-IV′ of FIG. 6.

The thin film transistor 300 having the structure of FIG. 6 and FIG. 7 further includes a metal layer 163 disposed on the bottom surface 120b of the concave part 125.

In detail, a thin film transistor 1500 according to another embodiment of the present disclosure includes a metal layer 163 on a substrate 110, and a seed layer 120 may be disposed on the metal layer 163. The seed layer 120 may have a concave part 125, and the metal layer 163 becomes a bottom surface of the concave part 125.

According to another embodiment of the present disclosure, the active layer 130 may contact the metal layer 163. Referring to FIG. 7, the active layer 130 may include a third connection part 130c that contacts the metal layer 163 disposed on the bottom surface 120b of the concave part 125.

The third connection part 130c that comes into contact with the bottom surface 120b of the concave part 125 of the active layer 130 is not crystallized. Therefore, the third connection part 130c may have an amorphous structure and may have excellent electrical conductivity. The third connection part 130c may not function as a channel part, but can function as a wiring portion.

The portion of the active layer 130 that comes into contact with the inclined surface 120s of the concave part 125 may be crystallized and serve as a channel part. Referring to FIG. 7, the inclined surfaces 120s of the concave part 125 may be separated by the bottom surface 120b and divided into two regions. Accordingly, the channel part 130n may be divided into a first channel part 130n1 and a second channel part 130n2.

The thin film transistor 300 of FIG. 7 may have a structure in which two channel parts 130n1, 130n2 are connected in series. The thin film transistor 300 of FIG. 7 corresponds to a structure in which two sub thin film transistors 1301, 1302 are connected in series. The gate electrodes 150 of the two sub thin film transistors 1301, 1302 are common.

For example, the first connection part 130a may become the source electrode 130al of the first sub-thin film transistor 1301, the first channel part 130n1 may become the channel part of the first sub-thin film transistor 1301, and the third connection part 130c may become the drain electrode 130b1 of the first sub-thin film transistor 1301.

Additionally, the second connection part 130b may become the drain electrode 130b2 of the second sub-thin film transistor 1302, the second channel part 130n2 may become the channel part of the second sub-thin film transistor 1302, and the third connection part 130c may become the source electrode 130a2 of the second sub-thin film transistor 1302.

Also, referring to FIG. 7, the gate insulating layer 140 may be patterned. The gate insulating layer 140 may be patterned, for example, in a shape corresponding to the gate electrode 150.

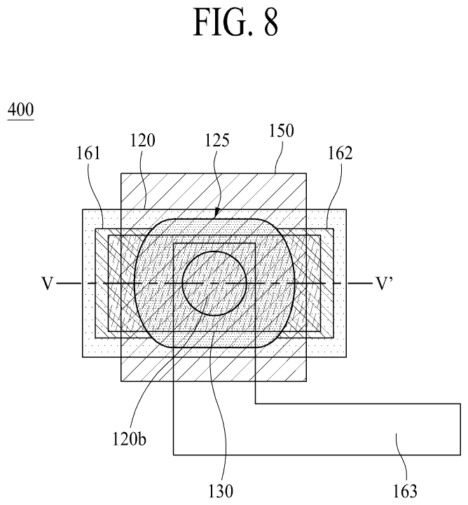

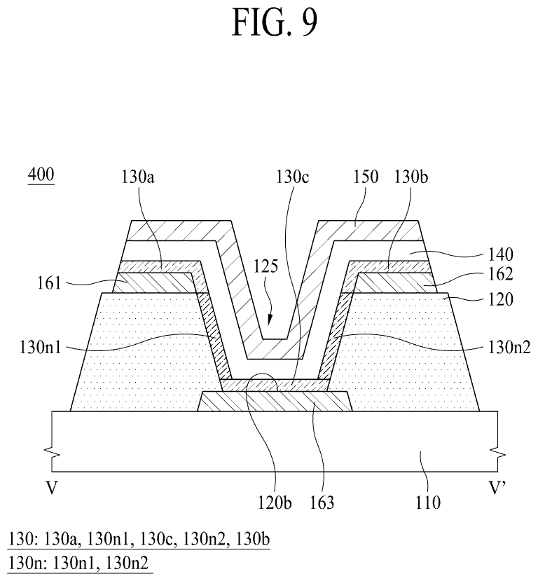

FIG. 8 is a plan view of a thin film transistor 400 according to another embodiment of the present disclosure, and FIG. 9 is a cross-sectional view taken along line V-V′ of FIG. 8.

According to another embodiment of the present disclosure, the concave part 125 may have various shapes.

Referring to FIG. 8, the concave part 125 may have an elliptical shape in plan-view. However, another embodiment of the present disclosure is not limited thereto, and the concave part 125 may have a circular or polygonal shape in plan-view.

In addition, referring to FIG. 8 and FIG. 9, the bottom surface 120b of the concave part 125 may have a circle shape in a plan view. As the bottom surface 120b of the concave part 125 may have a circle shape, the third connection part 130c may also have a circle shape in a plan view.

Additionally, the metal layer 163 may be an input terminal that inputs a signal to the thin film transistor 400 and may also be an output terminal that receives a signal from the thin film transistor 400.

Hereinafter, a manufacturing method of a thin film transistor according to one embodiment of the present disclosure will be described.

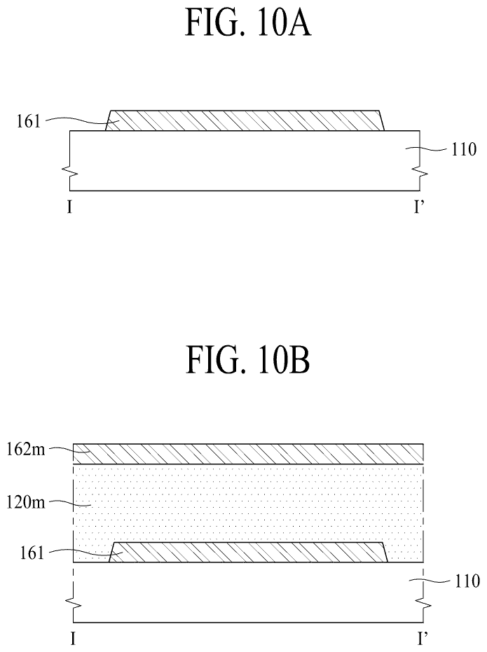

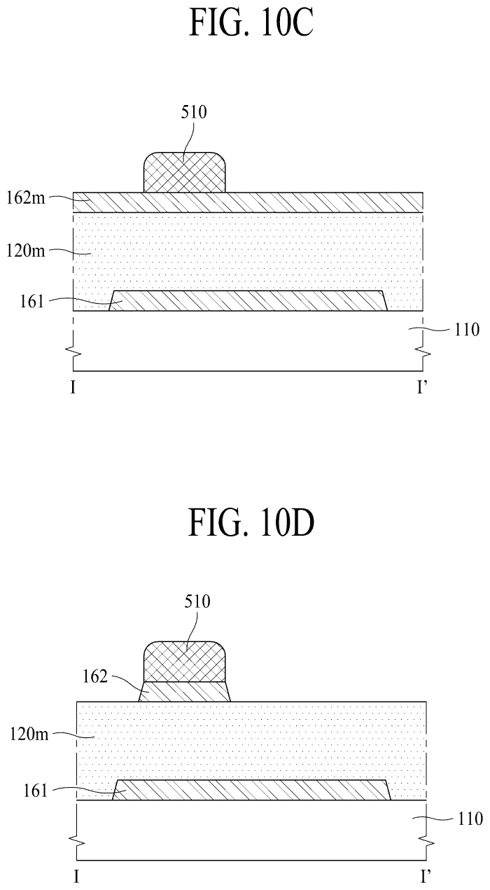

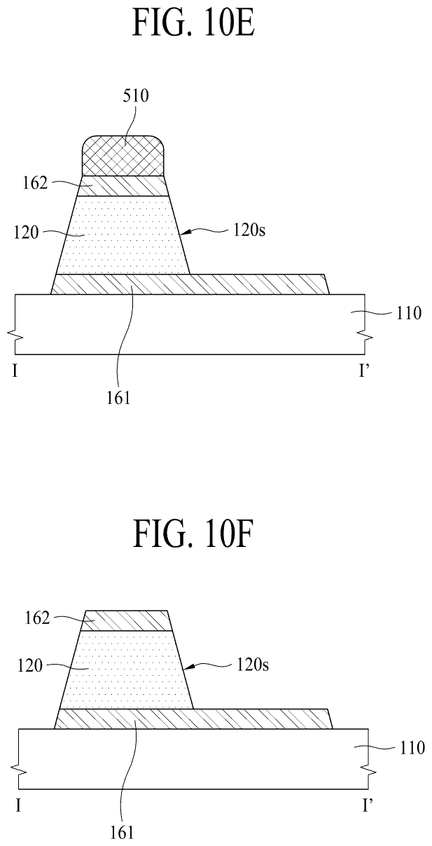

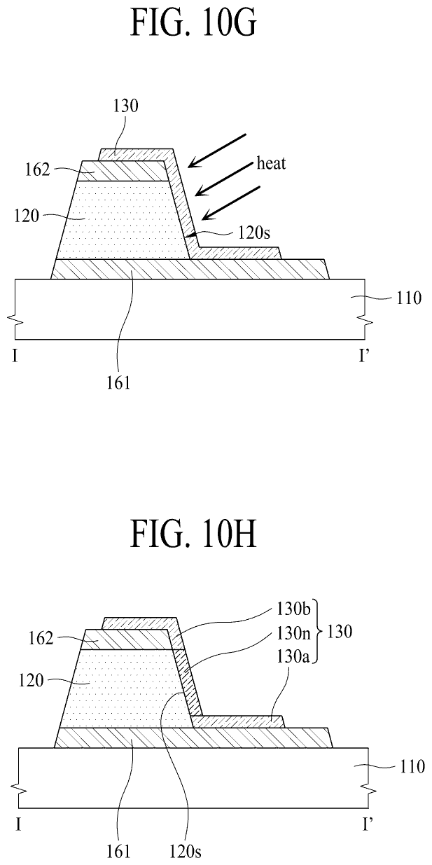

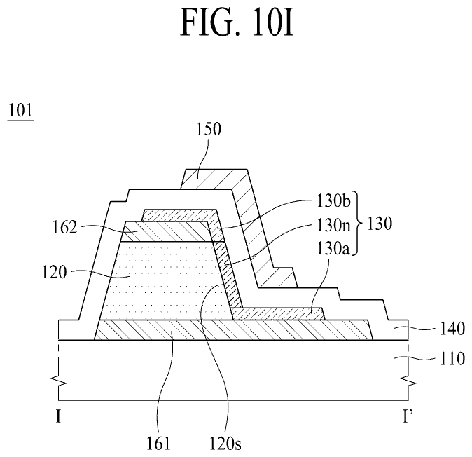

FIGS. 10A to 10I are cross-sectional views illustrating a manufacturing method of a thin film transistor 101 according to one embodiment of the present disclosure.

The manufacturing method of a thin film transistor 101 according to one embodiment of the present disclosure includes forming a seed material layer 120m on a substrate 110, forming a seed layer 120 having an inclined surface 120s by patterning the seed material layer 120m, forming an active layer 130 contacting the inclined surface 120s of the seed layer 120, heat treating the active layer 120 to crystallize a portion of the active layer 120 contacting the inclined surface 120s, and forming a gate electrode on the active layer 130,

The seed material layer 120m may be formed on a substrate 110.

In detail, referring to FIG. 10A, a source electrode 161 may be formed on a substrate 110.

And, referring to FIG. 10B, a seed material layer 120m and a drain material layer 162m may be formed on the source electrode 161.

Referring to FIG. 10C, a photoresist pattern 510 may be formed on a drain material layer 162m.

Referring to FIG. 10D, a drain material layer 162m may be patterned by etching using the photoresist pattern 510 as a mask. As a result, a drain electrode 162 may be formed.

Referring to FIG. 10E, the seed material layer 120m is patterned by additional etching process using the photoresist pattern 510 as a mask. As a result, the seed layer 120 may be formed. According to one embodiment of the present disclosure, the seed layer 120 having an inclined surface 120s may be formed by patterning the seed material layer 120m.

Referring to FIG. 10F, the photoresist pattern 510 is removed. The photoresist pattern 510 may be removed by an ashing process.

Referring to FIG. 10g, an active layer 130 may be formed on a seed layer 120. At least a portion of the active layer 130 may contact the seed layer 120. The active layer 130 may contact an inclined surface 120s of the seed layer 120.

The active layer 130 may have an amorphous structure. For example, the active layer 130 may be made of an amorphous oxide semiconductor material. The active layer 130 may have a high carrier concentration and may have electrical conductivity similar to that of a metal or conductor.

Next, the active layer 130 is heat treated. As the active layer 130 is heat treated, a portion of the active layer 130 that contacts the inclined surface 120s of the seed layer 120 may be crystallized.

According to one embodiment of the present disclosure, the active layer 130 may have an amorphous structure before heat treating, and through heat treating, a portion of the active layer 130 that contacts the seed layer 120 is crystallized.

The heat treating temperature may be 300 to 500° C. The heat treating temperature may vary depending on the thickness of the seed layer 120. The heat treating temperature may be referred to as a temperature of the heat treating.

Referring to FIG. 10H, as a result of heat treating, an active layer 130 including a crystalline portion and an amorphous portion may be formed.

The crystalline portion of the active layer 130 becomes the channel part 130n. The amorphous portion of the active layer 130 becomes the first connection part 130a and the second connection part 130b.

Referring to FIG. 10I a gate insulating layer 140 may be formed on the active layer 130, and a gate electrode 150 may be formed on the gate insulating layer 140. The gate electrode 150 may overlap at least partially with the active layer 130. In detail, the gate electrode 150 may be formed to overlap with a channel part 130n.

According to one embodiment of the present disclosure, at least a portion of the gate electrode 150 may be disposed facing the inclined surface 120s with the active layer 130 interposed therebetween.

As a result, a thin film transistor 101 according to one embodiment of the present disclosure may be manufactured as described above.

Hereinafter, a display apparatus including at least one of the thin film transistors described above will be described in detail.

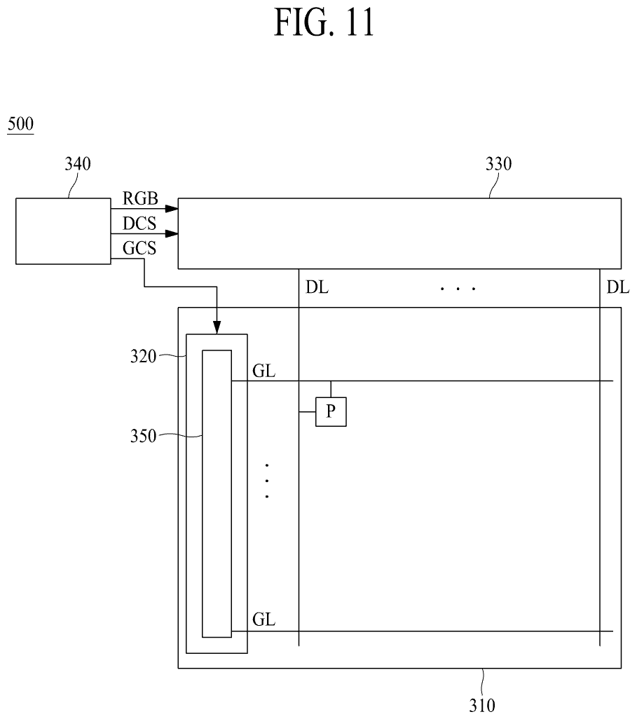

FIG. 11 is a schematic diagram of a display apparatus 500 according to another embodiment of the present disclosure.

A display apparatus 500 according to another embodiment of the present disclosure may include a display panel 310, a gate driver 320, a data driver 330, and a control unit 340.

The Gate lines GL and data lines DL are disposed on the display panel 310, and pixels P are disposed in the intersection area of the gate lines GL and data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from an external system, rearranges it, and supplies the redisposed image data RGB to the data driver 330.

The gate control signal GCS may include a gate start pulse GSP, a gate shift clock GSC, a gate output enable signal GOE, a start signal Vst, a gate clock GCLK, or the like. In addition, the gate control signal GCS may include control signals for controlling a shift register.

The data control signal DCS may include a source start pulse SSP, a source shift clock signal SSC, a source output enable signal SOE, a polarity control signal POL, or the like.

The data driver 330 supplies data voltage to the data lines DL of the display panel 310. In detail, the data driver 330 can convert image data RGB input from the control unit 340 into analog data voltage and supply the data voltage to the data lines DL.

The gate driver 320 sequentially supplies gate pulses GP to the gate lines GL during one frame. Here, one frame refers to a period during which one image is output through the display panel. In addition, the gate driver 320 supplies a gate off signal Goff capable of turning off the switching element to the gate lines GL during the remaining period during which the gate pulse GP is not supplied during one frame. Hereinafter, the gate pulse GP and the gate off signal Goff are collectively referred to as a scan signal SS.

According to one embodiment of the present disclosure, the gate driver 320 may be mounted on the substrate 110. In this way, a structure in which the gate driver 320 is directly mounted on the substrate 110 is called a Gate In Panel (GIP) structure.

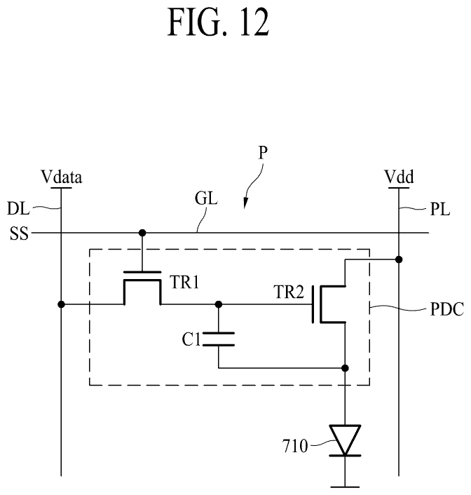

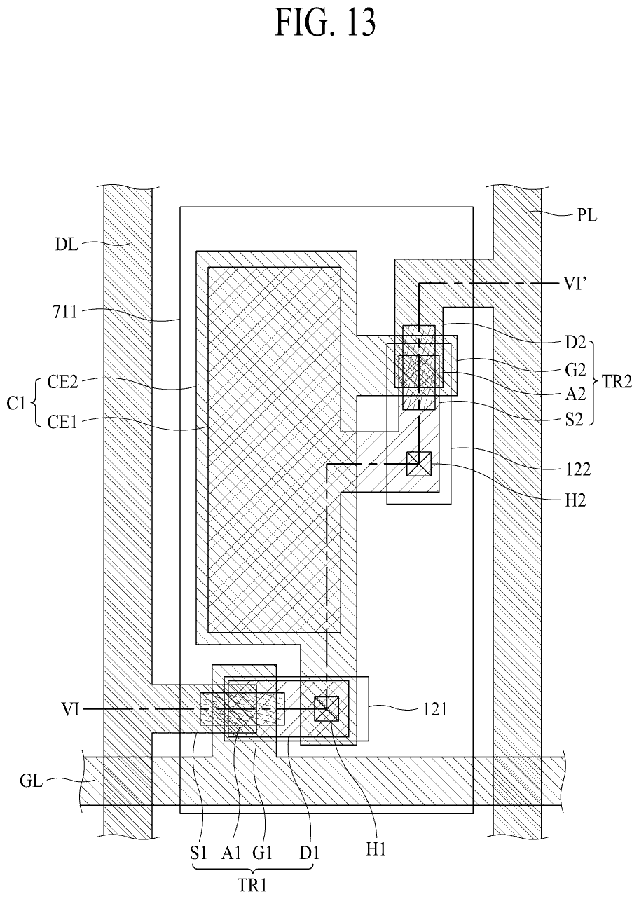

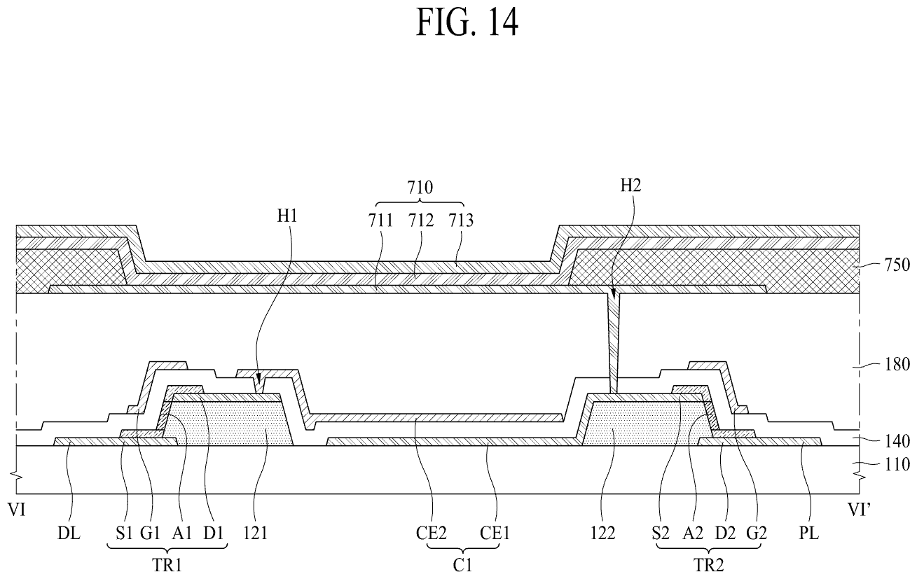

FIG. 12 is a circuit diagram for one pixel P of FIG. 11, FIG. 13 is a plan view for the pixel P of FIG. 12, and FIG. 14 is a cross-sectional view taken along line VI-VI′ of FIG. 13.

The circuit diagram of FIG. 12 is an equivalent circuit diagram for a pixel P of a display apparatus 500 including an organic light emitting diode OLED as a display element 710.

The pixel P includes a display element 710 and a pixel driver PDC that drives the display element 710.

The first thin film transistor TR1 is connected to the gate line GL and the data line DL, and is turned on or off by the scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

When the first thin film transistor TR1 is turned on by a scan signal SS applied through the gate line GL from the gate driver 320, the data voltage Vdata supplied through the data line DL is supplied to the gate electrode of the second thin film transistor TR2 connected to the display element 710. The data voltage Vdata is charged in the first capacitor C1 formed between the gate electrode and the source electrode of the second thin film transistor TR2. The first capacitor C1 is a storage capacitor Cst.

The amount of current supplied to the organic light emitting diode OLED, which is a display element 710, through the second thin film transistor TR2 is controlled according to the data voltage Vdata, and accordingly, the gradation of light output from the display element 710 may be controlled.

Referring to FIG. 13 and FIG. 14, a first thin film transistor TR1 and a second thin film transistor TR2 are disposed on a substrate 110.

The substrate 110 may be made of glass or plastic. As the substrate 110, a plastic having flexible property, for example, polyimide PI, may be used.

A data line DL and a driving power line PL are disposed on a substrate 110. In addition, a source electrode S1 of a first thin film transistor TR1 and a drain electrode D2 of a second thin film transistor TR2 are disposed on the substrate 110.

The source electrode S1 of the first thin film transistor TR1 may be formed integrally with the data line DL. The drain electrode D2 of the second thin film transistor TR2 may be formed integrally with the driving power line PL.

A seed layer 121 may be disposed on the source electrode S1 of the first thin film transistor TR1. Additionally, a seed layer 122 may be disposed on the drain electrode D2 of the second thin film transistor TR2.

A drain electrode D1 of a first thin film transistor TR1 may be disposed on a seed layer 121. Additionally, a source electrode S2 of a second thin film transistor TR2 may be disposed on a seed layer 122.

The source electrodes S1, S2 and the drain electrodes D1, D2 are distinguished only for convenience of explanation, and the source electrodes S1, S2 and the drain electrodes D1, D2 may be interchanged.

Referring to FIG. 13 and FIG. 14, the source electrode S2 of the second thin film transistor TR2 may extend onto the substrate 110 so that a portion thereof may become the first capacitor electrode CE1.

Active layers A1, A2 may be disposed on the seed layers 121, 122.

Referring to FIG. 14, an active layer A1 may be disposed on the source electrode S1, the drain electrode D1, and the seed layer 121 of the first thin film transistor TR1. The active layer A1 may contact the inclined surface of the seed layer 121.

Additionally, an active layer A2 may be disposed on the source electrode S2, the drain electrode D2 and the seed layer 122 of the second thin film transistor TR1. The active layer A2 may contact the inclined surface of the seed layer 122.

The active layers A1, A2 may include, for example, an oxide semiconductor material. The active layers A1, A2 may be formed of an oxide semiconductor layer made of an oxide semiconductor material. The active layers A1, A2 may include a crystalline portion and an amorphous portion. The channel part of the active layers A1, A2 may have a crystalline structure. A portion of the active layers A1, A2 that comes into contact with the seed layer 120 may be crystallized and have a crystalline structure.

A gate insulating layer 140 may be disposed on the active layers A1, A2. The gate insulating layer 140 may have insulating property and separates the active layers A1, A2 from the gate electrodes G1, G2. The gate insulating layer 140 can cover the entire surface of the active layers A1, A2.

A gate electrode G1 of a first thin film transistor TR1 and a gate electrode G2 of a second thin film transistor TR2 are disposed on a gate insulating layer 140.

The gate electrode G1 of the first thin film transistor TR1 overlaps at least partly with the active layer A1 of the first thin film transistor TR1. The gate electrode G2 of the second thin film transistor TR2 overlaps at least partly with the active layer A2 of the second thin film transistor TR2.

Referring to FIG. 13 and FIG. 14, a second capacitor electrode CE2 may be disposed on the same layer as the gate electrodes G1, G2. The second capacitor electrode CE2 may be connected to the drain electrode D1 of the first thin film transistor TR1 through a contact hole H1. In addition, a part of the second capacitor electrode CE2 may extend to an upper portion of the active layer A1 of the second thin film transistor TR2 to become the gate electrode G2 of the second thin film transistor TR2.

Alternatively, it may be the gate electrode G2 of the second thin film transistor TR2 extends over the gate insulating layer 140 and functions as a second capacitor electrode CE2.

The second capacitor electrode CE2 overlaps the first capacitor electrode CE1. The first capacitor electrode CE1 and the second capacitor electrode CE2 overlap to form a first capacitor C1.

A planarization layer 180 may be disposed on the gate electrodes G1, G2 and the second capacitor electrode CE2. An interlayer insulating film may be further disposed under the planarization layer 180.

The planarization layer 180 planarizes the upper portions of the first thin film transistor TR1 and the second thin film transistor TR2 and protects the first thin film transistor TR1 and the second thin film transistor TR2.

A first electrode 711 of a display element 710 may be disposed on a planarization layer 180. The first electrode 711 of the display element 710 may be connected to a source electrode S2 of a second thin film transistor TR2 through a contact hole H2 formed in the planarization layer 180.

A bank layer 750 may be disposed at the edge of the first electrode 711. The bank layer 750 defines a light emitting area of the display element 710.

An organic light emitting layer 712 may be disposed on a first electrode 711, and a second electrode 713 may be disposed on the organic light emitting layer 712. Accordingly, a display element 710 is completed. The display element 710 illustrated in FIG. 14 is an organic light emitting diode OLED. Therefore, a display apparatus 100 according to an embodiment of the present disclosure is an organic light emitting display apparatus.

A pixel driver PDC according to another embodiment of the present disclosure may be formed in various structures other than the structures described above. The pixel driver PDC may include, for example, three or more thin film transistors and two or more capacitors.

The present disclosure described above is not limited to the above-described embodiments and the attached drawings, and it will be apparent to a person skilled in the art to which the present disclosure pertains that various substitutions, modifications, and changes are possible within a scope that does not depart from the technical details of the present disclosure.

The thin film transistor according to one embodiment of the present disclosure may have a vertical structure including a channel part disposed on an inclined surface of a seed layer. Since the channel part may have a vertical structure, the length of the channel part may be secured even in a narrow area. Accordingly, the area occupied by the thin film transistor according to one embodiment of the present disclosure is small. In addition, when the thin film transistor according to one embodiment of the present disclosure is used, integration of elements is possible.

The thin film transistor according to one embodiment of the present disclosure includes a seed layer and an active layer contacting the seed layer, and a portion of the active layer contacting the seed layer may have a crystalline structure. A portion of the active layer having the crystalline structure may be a channel part. According to one embodiment of the present disclosure, the channel part of the thin film transistor may have a crystalline structure and thus may have excellent resistance to hydrogen, and the channel part may have excellent electrical stability. Therefore, the thin film transistor according to one embodiment of the present disclosure may have excellent electrical stability.

According to one embodiment of the present disclosure, a thin film transistor may be manufactured without going through a conductorization process.

In one embodiment, a thin film transistor includes a substrate 110, a seed layer 120 disposed on the substrate 110, and an active layer 130 formed adjacent to at least one inclined surface of the seed layer 120. The seed layer 120 may be formed from an oxide semiconductor material and patterned to exhibit a sloped or angled profile, which enables the formation of a vertical or slanted channel in the active layer 130. The active layer 130 includes a crystalline channel part that is disposed on the inclined surface of the seed layer 120, and amorphous connection parts located on opposing sides of the channel part. The channel part may be selectively crystallized by thermal treatment, while the surrounding amorphous regions retain high conductivity characteristics.

A gate insulating layer 140 is formed over the active layer 130, and a gate electrode 150 is disposed to face at least the channel part with the gate insulating layer 140 interposed therebetween. In some embodiments, the gate electrode 150 includes a non-planar segment shaped to follow the contour or profile of the inclined surface, thereby ensuring close alignment with the crystallized channel part. This configuration allows for strong electrostatic coupling and effective modulation of the channel, even in geometrically compact structures.

The thin film transistor may further include source and drain electrodes formed in electrical contact with the amorphous connection parts of the active layer. In one example, the source electrode 161 is in contact with a first amorphous connection part located on one end of the channel part, and the drain electrode 162 is in contact with a second amorphous connection part on the opposite side of the channel. These regions may be sufficiently conductive to facilitate charge injection and collection without requiring additional doping or conductorization steps.

In another embodiment, the seed layer 120 includes a concave part defined by two opposing inclined surfaces and a bottom surface that connects the inclined surfaces. The active layer 130 may be formed to extend continuously and contiguously along the two inclined surfaces and the bottom surface, thereby forming a curved or U-shaped channel profile. The portions of the active layer contacting the inclined surfaces may form first and second crystalline channel parts, while the portion disposed along the bottom surface may remain amorphous and serve as a connection part.

Optionally, a conductive layer 163 may be disposed at the bottom of the concave part and positioned in contact with the amorphous connection part of the active layer. This metal layer may act as a contact node or signal routing line, providing a low-resistance path to or from the central portion of the active layer. The structure allows two crystalline regions to be connected in series, while still maintaining spatial compactness and vertical integration.

In a plan view, the seed layer 120 may be wider than the active layer 130 in the region of overlap with the gate electrode 150. This arrangement ensures that the channel region of the active layer is completely formed on the seed layer 120 and avoids unintended conductive paths through the amorphous connection regions. By maintaining proper overlap, electrical isolation and reliable switching behavior are preserved.

In a further embodiment, the above-described thin film transistors may be incorporated into each pixel of a display apparatus, such as an organic light emitting diode (OLED) display panel. Each pixel may include a thin film transistor in which the seed layer defines a concave part with a first inclined surface, a second inclined surface, and a bottom surface. The active layer is formed along these surfaces to create first and second crystalline channel parts on the inclined surfaces and an amorphous connection part bridging them at the bottom.

The gate electrode in such configurations may be disposed to overlap at least the two crystalline channel parts with a gate insulating layer in between. A metal layer 163 may optionally be provided in contact with the amorphous connection part at the bottom surface of the seed layer, providing an electrical interface for driving signals. In addition, the first and second crystalline channel parts may each extend to respective amorphous connection regions outside the concave part, which are contacted by source and drain electrodes.

The seed layer and the semiconductor active layer may share at least one common metal element, such as indium or gallium, to enhance lattice compatibility and interfacial adhesion. Furthermore, in some embodiments, the use of a concave seed structure enables an increased effective channel length without expanding the lateral footprint of the pixel. This architecture is particularly beneficial for enhancing switching performance and achieving high resolution in compact display panels.

In addition to the effects mentioned above, other features and advantages of the present disclosure are described below or may be clearly understood by those skilled in the art to which the present disclosure pertains from such description and explanation.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
a seed layer having an inclined surface;
an active layer contacting the seed layer and including a channel part; and
a gate electrode overlapping at least a portion of the active layer in a plan view,
wherein the channel part has a crystalline structure,
wherein the channel part is disposed on the inclined surface and contacts the inclined surface, and
wherein at least a portion of the gate electrode is disposed to face the inclined surface with the active layer interposed therebetween.

2. The thin film transistor of claim 1,
wherein the active layer further comprises:
a first connection part connected to one side of the channel part; and
a second connection part connected to the other side of the channel part,
wherein each of the first connection part and second connection part has an amorphous structure, and
wherein the seed layer has an amorphous structure.

3. The thin film transistor of claim 2,
wherein the first connection part and second connection part do not contact the seed layer.

4. The thin film transistor of claim 2,
wherein, in a plan view, in a portion where the gate electrode is disposed, a width of the seed layer is greater than a width of the active layer, and
wherein the width of the seed layer and the width of the active layer are measured in a direction perpendicular to a line connecting the first connection part and second connection part.

5. The thin film transistor of claim 1,
wherein the seed layer is an amorphous layer, in which a ratio of a sum of areas of crystals having a grain size of 1 nm or more is 10% or less to an entire cross-sectional area in a cross-section of the seed layer.

6. The thin film transistor of claim 1,
wherein the seed layer has a lower carrier concentration than the channel part and has a carrier concentration of 1.0×10¹⁶ ea/cm³ or less.

7. The thin film transistor of claim 1,
wherein the seed layer includes at least one oxide semiconductor material selected from IZO (InZnO) based oxide semiconductor material, IGZO (InGaZnO) based oxide semiconductor material, IGZTO (InGaZnSnO) based oxide semiconductor material, GZTO (GaZnSnO) based oxide semiconductor material, GZO (GaZnO) based oxide semiconductor material, and GO (GaO) based oxide semiconductor material.

8. The thin film transistor of claim 1,
wherein the active layer includes at least one oxide semiconductor material selected from IGZO (InGaZnO) based oxide semiconductor material, IGO (InGaO) based oxide semiconductor material, IGZTO (InGaZnSnO) based oxide semiconductor material, GZTO (GaZnSnO) based oxide semiconductor material, GZO (GaZnO) based oxide semiconductor material, GO (GaO) based oxide semiconductor material, TO (SnO) based oxide semiconductor material, ITO (InSnO) based oxide semiconductor material, ITZO (InSnZnO) based oxide semiconductor material, IZO (InZnO) based oxide semiconductor material, ZO (ZnO) based oxide semiconductor material, InO (InO) based oxide semiconductor material, and FIZO (FeInZnO) based oxide semiconductor material.

9. The thin film transistor of claim 8,
wherein the active layer further includes at least one element selected from beryllium (Be), boron (B), carbon (C), aluminum (Al), silicon (Si), iron (Fe), calcium (Ca), tin (Sn), titanium (Ti), tantalum (Ta), vanadium (V), yttrium (Y), and zirconium (Zr).

10. The thin film transistor of claim 1,
wherein the seed layer and the active layer include at least one common metal element.

11. The thin film transistor of claim 1,
wherein, in a cross-section of the channel part, a ratio of sum of areas of crystals having a grain size of 1 nm or more is 50% or more to an entire cross-sectional area.

12. The thin film transistor of claim 1,
wherein the channel part includes at least one crystal plane selected from a (400) crystal plane, a (222) crystal plane, a (220) crystal plane, a (311) crystal plane, and a (001) crystal plane.

13. The thin film transistor of claim 2 further comprising:
a source electrode and a drain electrode spaced apart from each other,
wherein the source electrode contacts the seed layer and the first connection part, and
wherein the drain electrode contacts the seed layer and the second connection part.

14. The thin film transistor of claim 1,
wherein the seed layer has a concave part,
wherein the concave part is defined by the inclined surface and a bottom surface, and
wherein the active layer is disposed on the inclined surface and on the bottom surface of the concave part.

15. The thin film transistor of claim 14,
wherein the bottom surface is a part of the seed layer, and
wherein the channel part is extended from on the inclined surface to on the bottom surface.

16. The thin film transistor of claim 14 further comprising:
a metal layer on the bottom surface of the concave part,
wherein the active layer further includes a third connection part contacting the metal layer,
wherein the third connection part has an amorphous structure.

17. A manufacturing method of a thin film transistor comprising:
forming a seed material layer on a substrate;
patterning the seed material layer;
forming a seed layer having an inclined surface by the patterning;
forming an active layer contacting the inclined surface of the seed layer;
heat treating the active layer to crystallize a portion of the active layer contacting the inclined surface; and
forming a gate electrode on the active layer,
wherein at least a portion of the gate electrode is disposed to face the inclined surface with the active layer interposed therebetween.

18. The manufacturing method of claim 17,
wherein, before the heat treating, the active layer has an amorphous structure,
wherein heat treating the active layer contacting the inclined surface causes to form a crystalline channel region while other regions remain amorphous.

19. The manufacturing method of claim 17,
wherein a temperature of the heat treating is in the range of 300 to 500° C.

20. A device comprising:
a substrate;
a seed layer on the substrate, the seed layer having at least one inclined surface;
an active layer adjacent to the at least one inclined surface of the seed layer, the active layer including a crystalline channel part on the at least one inclined surface and amorphous connection parts on opposing sides of the channel part; and
a gate electrode facing the channel part with a gate insulating layer interposed therebetween,
wherein the gate electrode includes a non-planar segment that is shaped to follow a profile of the crystallized channel part disposed along the seed layer.

21. The device of claim 20, further comprising source and drain electrodes each in electrical contact with a respective one of the amorphous connection part.

23. The device of claim 20, wherein the seed layer includes a concave part defined by two inclined surfaces and a bottom surface connecting them.

24. The device of claim 23, wherein the active layer extends continuously and contiguously along the two inclined surfaces and the bottom surface of the concave part.

25. The device of claim 23, further comprising a conductive layer disposed at a bottom surface of the concave part and in contact with the connection part of the active layer.

26. The device of claim 20, wherein the gate electrode overlaps the at least one inclined surface of the seed layer in plan view.

27. A display apparatus comprising:
a plurality of pixels, each pixel including a thin film transistor, wherein each thin film transistor includes:
a seed layer with a concave part including:
a first inclined surface;
a second inclined surface opposing the first inclined surface; and
a bottom surface connecting the first and second inclined surfaces;
a semiconductor active layer on the first inclined surface, the second inclined surface, and the bottom surface, the active layer comprising:
a first crystalline channel part located on the first inclined surface;
a second crystalline channel part located on the second inclined surface;
an amorphous connection part on the bottom surface and connecting the first and second crystalline channel parts;
a gate electrode on the active layer and overlapping at least the first and second crystalline channel parts with a gate insulating layer interposed therebetween.

28. The display apparatus of claim 27, further comprising:
a metal layer adjacent to the bottom surface of the seed layer and in electrical contact with the amorphous connection part of the active layer.

29. The display apparatus of claim 27, further comprising:
a first amorphous connection part extending from the first crystalline channel part away from the concave part;
a second amorphous connection part extending from the second crystalline channel part away from the concave region;
a source electrode electrically connected to the first amorphous connection part;
a drain electrode electrically connected to the second amorphous connection part.

30. The display apparatus of claim 27, wherein the seed layer and the semiconductor active layer share at least one common metal element.

31. The display apparatus of claim 27, wherein a width of the seed layer, in plan view, is greater than a width of the active layer in a region of overlap with the gate electrode.

32. The display apparatus of claim 27, wherein, in operation, the concave part of the seed layer increases effective channel length of the thin film transistor.
